(19) United States
(12) Patent Application Publication
(10) Pub. No.: US 2024/0153562 A1
(43) Pub. Date: May 9, 2024

(54) SEMICONDUCTOR MEMORY DEVICE

(71) Applicant: KIOXIA CORPORATION, Tokyo (JP)

(72) Inventor: Takeshi HIOKA, Machida (JP)

(73) Assignee: KIOXIA CORPORATION, Tokyo (JP)

(21) Appl. No.: 18/417,402

(22) Filed: Jan. 19, 2024

Related U.S. Application Data
(63) Continuation of application No. PCT/JP2021/045532, filed on Dec. 10, 2021.

(30) Foreign Application Priority Data
Jul. 21, 2021 (JP) 2021-120725

(51) Int. Cl. G11C 16/16; G11C 16/04; G11C 16/26

(52) U.S. Cl. CPC G11C 16/16; G11C 16/0483; G11C 16/26

(57) ABSTRACT

A semiconductor memory device includes: a first wiring; a first memory transistor; a first transistor; a second memory transistor; a second transistor; a second wiring connected to a gate electrode of the first memory transistor; a third wiring; a first gate wiring connected to a gate electrode of the first transistor; a second gate wiring connected to a gate electrode of the second transistor; and a control circuit configured to execute an erase operation that selects the first or the second memory transistor. The control circuit controls a voltage of the first gate wiring to become larger than a voltage of the second wiring and controls a voltage of the second gate wiring to become larger than the voltage of the first gate wiring in the erase operation performed with the first memory transistor selected.

### CROSS-REFERENCE TO RELATED APPLICATIONS

This is a continuation application of PCT International Application No. PCT/JP2021/045532 filed on Dec. 10, 2021, designating the United States of America, which is based on and claims priority of Japanese Patent Application No. 2021-120725 filed on Jul. 21, 2021. The entire disclosures of the above-identified applications, including the specifications, drawings and claims are incorporated herein by reference in their entirety.

### BACKGROUND

### Field

Embodiments described herein relate generally to a semiconductor memory device.

### Description of the Related Art

There has been known a semiconductor memory device that includes a memory cell array including a plurality of memory cells and a peripheral circuit that is connected to this memory cell array and outputs user data according to input of a command set including command data and address data.

### BRIEF DESCRIPTION OF THE DRAWINGS

FIG. 1 is a schematic block diagram illustrating a configuration of a memory system 10 according to a first embodiment;

FIG. 2 is a schematic side view illustrating an exemplary configuration of the memory system 10;

FIG. 3 is a schematic plan view illustrating an exemplary configuration of the memory system 10;

FIG. 4 is a schematic block diagram illustrating a configuration of a memory die MD;

FIG. 5 is a schematic circuit diagram illustrating a configuration of a part of the memory die MD;

FIG. 6 is a schematic perspective view illustrating a configuration of a part of the memory die MD;

FIG. 7 is a schematic cross-sectional view illustrating a configuration of a part of the memory die MD;

FIG. 8 is a schematic cross-sectional view illustrating a configuration of a part of the memory die MD;

FIG. 9 is a schematic cross-sectional view illustrating a configuration of a part of the memory die MD;

FIG. 10 is a schematic circuit diagram illustrating a configuration of a part of the memory die MD;

FIG. 11 is a schematic circuit diagram illustrating a configuration of a part of the memory die MD;

FIG. 12 is a schematic waveform diagram for describing an operation method of the memory die MD;

FIG. 13 is a schematic cross-sectional view for describing the operation method of the memory die MD;

FIG. 14 is a schematic waveform diagram for describing the operation method of the memory die MD;

FIG. 15 is a schematic cross-sectional view for describing the operation method of the memory die MD;

FIG. 16 is a schematic waveform diagram for describing the operation method of the memory die MD;

FIG. 17 is a schematic cross-sectional view for describing the operation method of the memory die MD;

FIG. 18 is a schematic circuit diagram illustrating a configuration of a part of the memory die MD;

FIG. 19 is a schematic circuit diagram illustrating a configuration of a part of a semiconductor memory device according to a comparative example;

FIG. 20 is a schematic cross-sectional view for describing an erase operation of the semiconductor memory device according to the comparative example;

FIG. 21 is a schematic circuit diagram illustrating a configuration of a part of a semiconductor memory device according to a modification;

FIG. 22 is a schematic waveform diagram for describing an erase operation of a semiconductor memory device according to a second embodiment; and

FIG. 23 is a schematic waveform diagram for describing an erase operation of a semiconductor memory device according to a third embodiment.

### DETAILED DESCRIPTION

A semiconductor memory device according to one embodiment includes: a first wiring; a first memory transistor connected to the first wiring; a first transistor connected between the first wiring and the first memory transistor; a second memory transistor connected to the first wiring in parallel with the first memory transistor; a second transistor connected between the first wiring and the second memory transistor; a second wiring connected to a gate electrode of the first memory transistor; a third wiring connected to a gate electrode of the second memory transistor; a first gate wiring connected to a gate electrode of the first transistor; a second gate wiring connected to a gate electrode of the second transistor; and a control circuit configured to be able to execute an erase operation that selects the first memory transistor or the second memory transistor and erases data. The control circuit is configured to be able to control a voltage of the first gate wiring to become larger than a voltage of the second wiring and controls a voltage of the second gate wiring to become larger than the voltage of the first gate wiring in the erase operation performed with the first memory transistor selected.

Next, the semiconductor memory devices according to embodiments are described in detail with reference to the drawings. The following embodiments are only examples, and not described for the purpose of limiting the present invention.

In this specification, when referring to a “semiconductor memory device”, it may mean a memory die (a memory chip) and may mean a memory system including a controller die, such as a memory card and an SSD. Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

### First Embodiment

[Memory System 10]

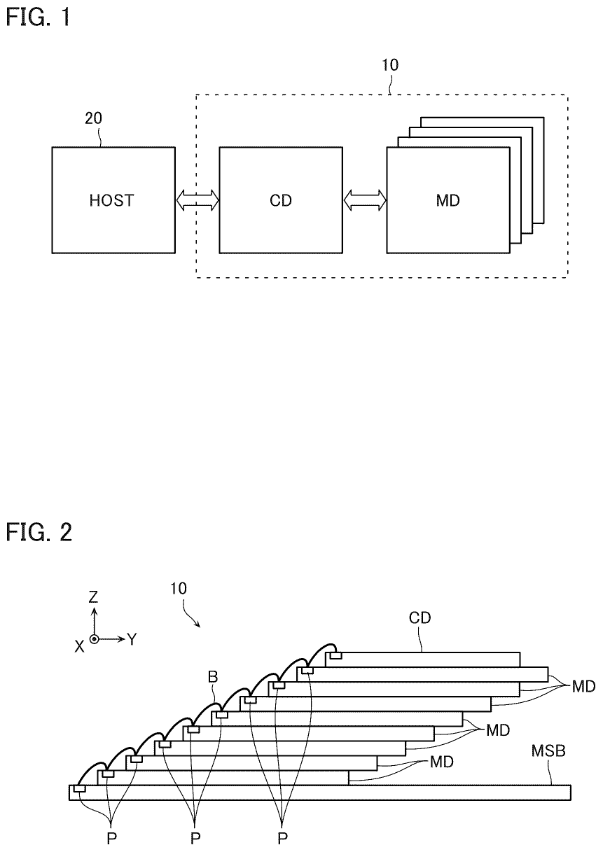

FIG. 1 is a schematic block diagram illustrating a configuration of the memory system 10 according to the first embodiment.

The memory system 10 performs read, write, erase of user data, and the like in response to a signal transmitted from a host computer 20. The memory system 10 is, for example, any system that can store user data including a memory card and an SSD. The memory system 10 includes a plurality of memory dies MD that store the user data and a controller die CD connected to these plurality of memory dies MD and the host computer 20. The controller die CD includes, for example, a processor, a RAM, and the like, and performs processes, such as conversion between a logical address and a physical address, bit error detection/correction, a garbage collection (compaction), and a wear leveling.

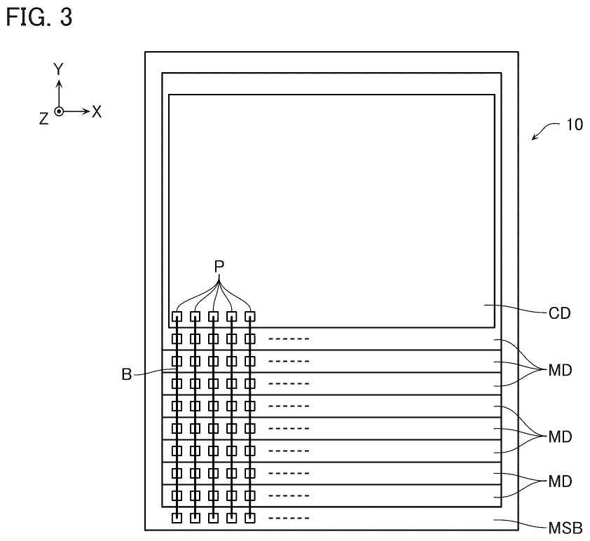

FIG. 2 is a schematic side view illustrating an exemplary configuration of the memory system 10 according to the embodiment. FIG. 3 is a schematic plan view illustrating the exemplary configuration. For convenience of description, FIG. 2 and FIG. 3 omit a part of the configuration.

As illustrated in FIG. 2, the memory system 10 according to the embodiment includes a mounting substrate MSB, the plurality of memory dies MD stacked on the mounting substrate MSB, and the controller die CD stacked on the memory dies MD. On an upper surface of the mounting substrate MSB, a pad electrode P is disposed in a region at an end portion in a Y-direction, and another part of the region is bonded to a lower surface of the memory die MD via an adhesive and the like. On an upper surface of the memory die MD, the pad electrode P is disposed in a region at an end portion in the Y-direction, and other regions are bonded to a lower surface of another memory die MD or the controller die CD via the adhesive and the like. On an upper surface of the controller die CD, the pad electrode P is disposed in a region at an end portion in the Y-direction.

As illustrated in FIG. 3, the mounting substrate MSB, the plurality of memory dies MD, and the controller die CD each include a plurality of the pad electrodes P arranged in an X-direction. The plurality of pad electrodes P disposed on each of the mounting substrate MSB, the plurality of memory dies MD, and the controller die CD are mutually connected via bonding wires B.

Note that the configurations illustrated in FIG. 2 and FIG. 3 are merely examples, and specific configurations are appropriately adjustable. For example, in the examples illustrated in FIG. 2 and FIG. 3, the controller die CD is stacked on the plurality of memory dies MD, and these configurations are connected with the bonding wires B. In such a configuration, the plurality of memory dies MD and the controller die CD are included in one package. However, the controller die CD may be included in a package different from the memory die MD. Additionally, the plurality of memory dies MD and the controller die CD may be connected to one another via through electrodes or the like, not the bonding wires B.

[Configuration of Memory Die MD]

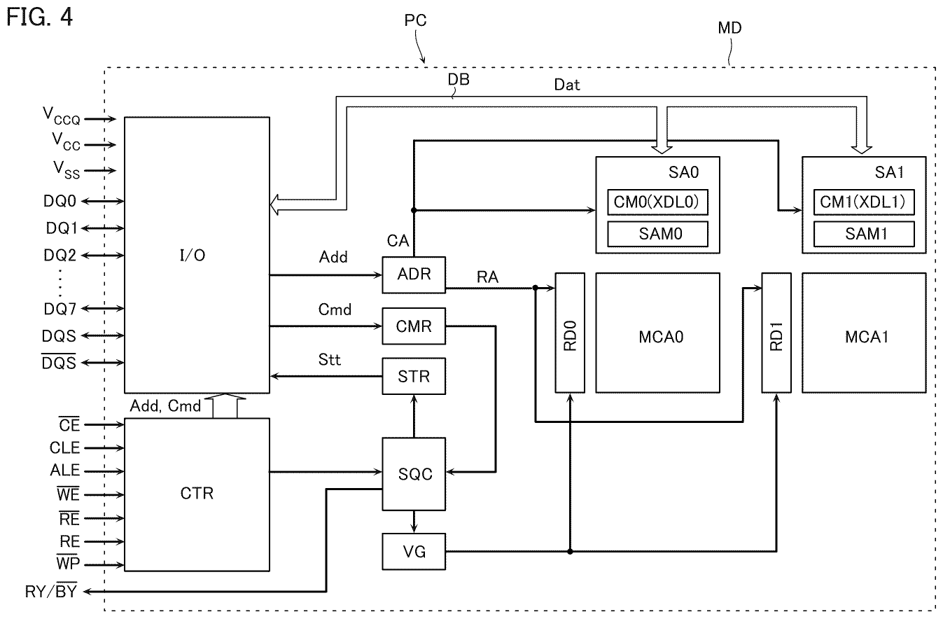

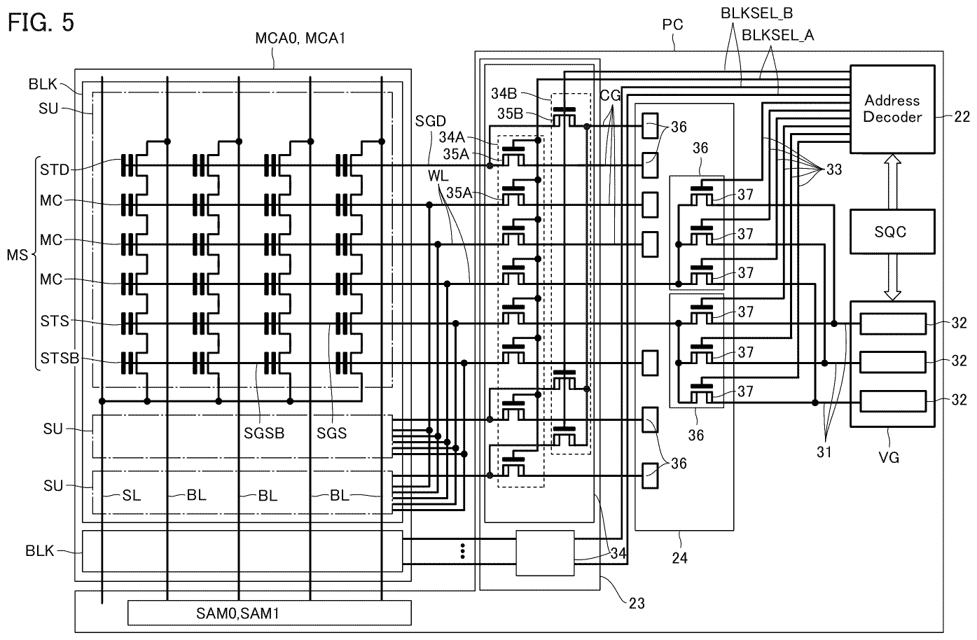

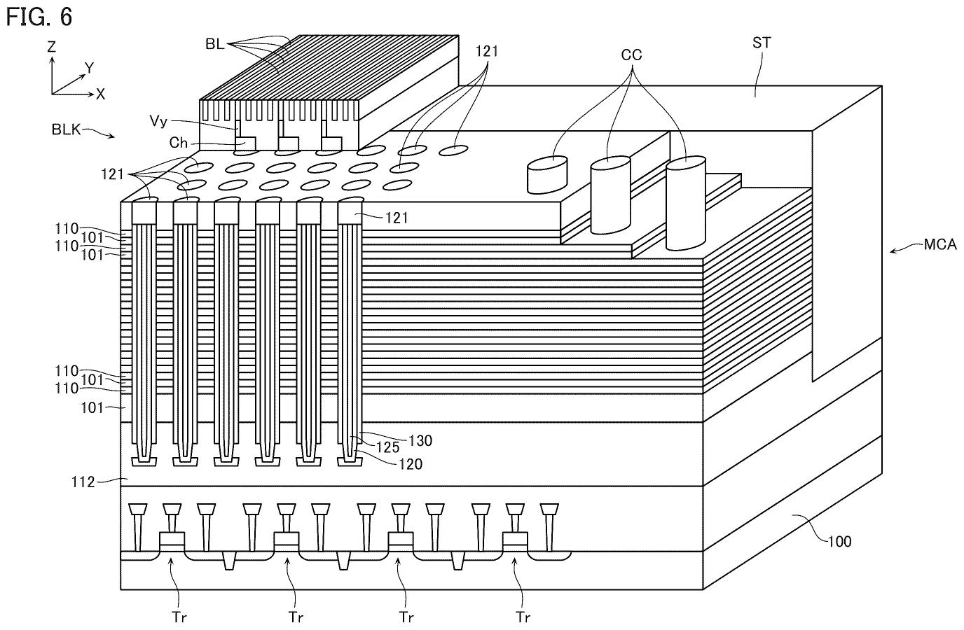

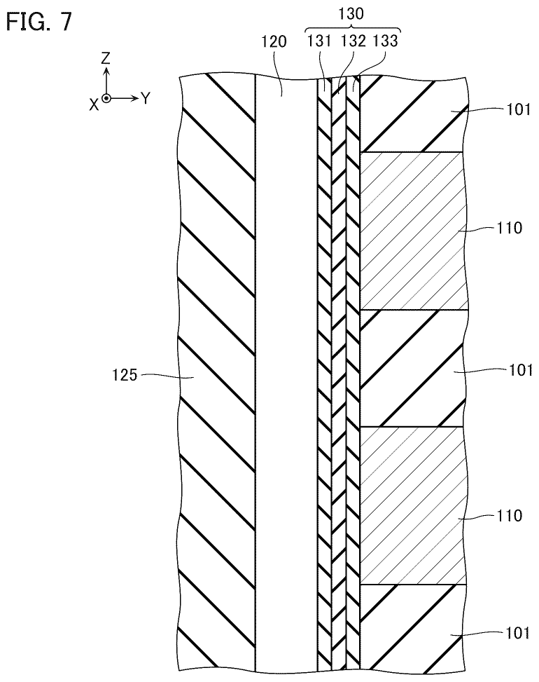

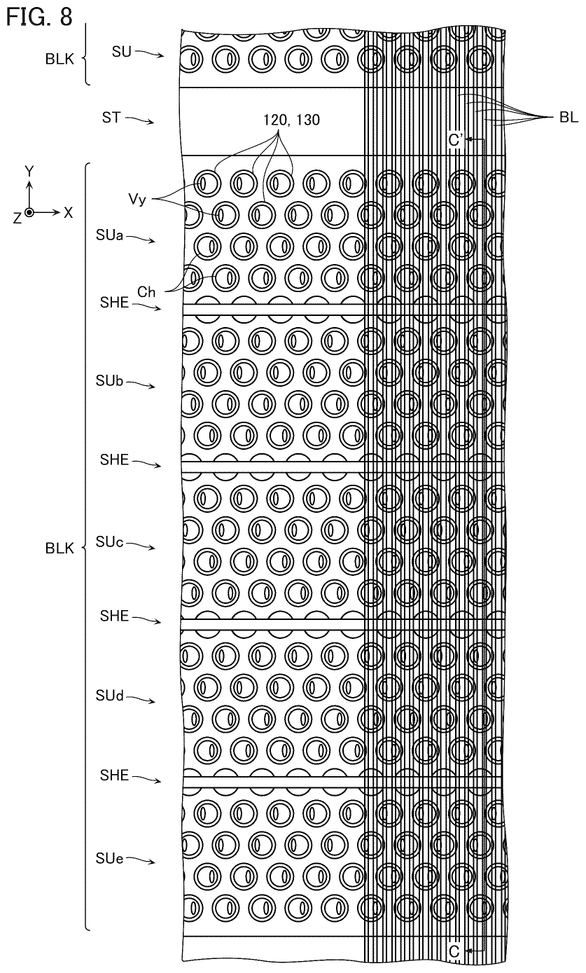

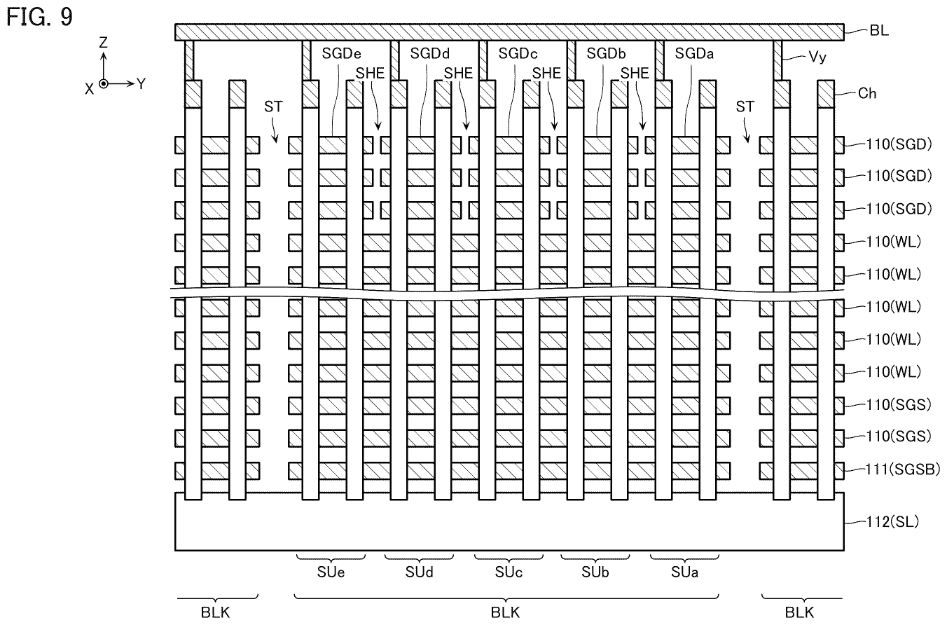

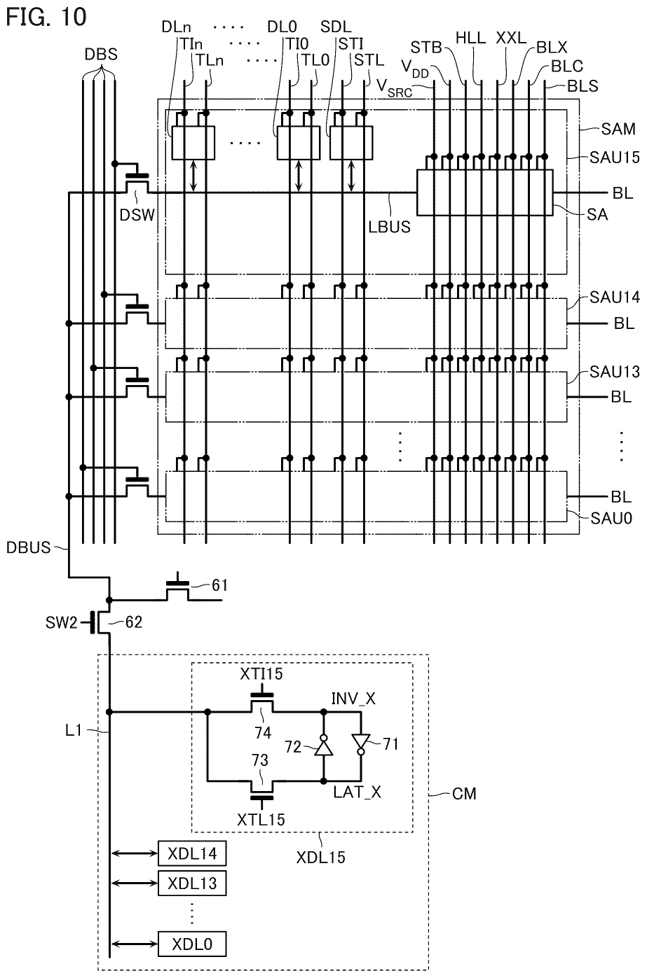

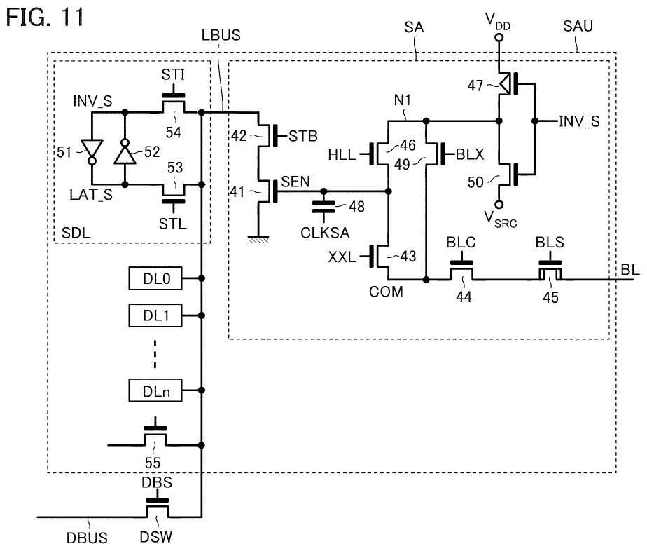

FIG. 4 is a schematic block diagram illustrating a configuration of the memory die MD according to the first embodiment. FIG. 5 is a schematic circuit diagram illustrating a configuration of a part of the memory die MD. FIG. 6 is a schematic perspective view illustrating a configuration of a part of the memory die MD. FIG. 7 and FIG. 8 are schematic cross-sectional views illustrating configurations of parts of the memory die MD. FIG. 9 is a schematic cross-sectional view of a structure illustrated in FIG. 8 taken along line C-C′ and viewed along an arrow direction. FIG. 10 and FIG. 11 are schematic circuit diagrams illustrating configurations of parts of the memory die MD. In FIG. 4 to FIG. 11, for sake of convenient description, a part of the configuration is omitted.

Note that FIG. 4 illustrates, for example, a plurality of control terminals. These plurality of control terminals are expressed as control terminals corresponding to high active signals (positive logic signals) in some cases, expressed as control terminals corresponding to low active signals (negative logic signals) in some cases, and expressed as control terminals corresponding to both of the high active signals and the low active signals in some cases. In FIG. 4, reference numerals of the control terminals corresponding to the low active signals include overlines (overbars). In this specification, a reference numeral of the control terminal corresponding to the low active signal includes a slash (“/”). Note that the description in FIG. 4 is an example, and the specific aspect is appropriately adjustable. For example, a part of or all the high active signals can be changed to the low active signals, or a part of or all the low active signals can be changed to the high active signals.

As illustrated in FIG. 4, the memory die MD includes memory cell arrays MCA0, MCA1 storing the user data and a peripheral circuit PC connected to the memory cell arrays MCA0, MCA1. In the following description, the memory cell arrays MCA0, MCA1 are referred to as a memory cell array MCA in some cases.

[Configuration of Memory Cell Array MCA]

As illustrated in FIG. 5, the memory cell array MCA includes a plurality of memory blocks BLK. These plurality of memory blocks BLK each include a plurality of string units SU. These plurality of string units SU each include a plurality of memory strings MS. These plurality of memory strings MS have one ends each connected to the peripheral circuit PC via bit lines BL. These plurality of memory strings MS have other ends each connected to the peripheral circuit PC via a common source line SL.

The memory string MS includes a drain-side select transistor STD, a plurality of memory cells MC (memory cell transistors), a source-side select transistor STS, and a source-side select transistor STSB, which are connected in series between the bit line BL and the source line SL. Hereinafter, the drain-side select transistor STD, the source-side select transistor STS, and the source-side select transistor STSB may be simply referred to as select transistors (STD, STS, STSB) or select transistors (STD, STS).

The memory cell MC is a field-effect type transistor that includes a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores the user data of one bit or a plurality of bits. Respective word lines WL are connected to gate electrodes of the plurality of memory cells MC corresponding to one memory string MS. Each of these word lines WL is connected to all the memory strings MS in one memory block BLK in common.

The select transistors (STD, STS, STSB) are field-effect type transistors that include a semiconductor layer, a gate insulating film, and a gate electrode. The semiconductor layer functions as a channel region. A drain-side select gate line SGD, a source-side select gate line SGS, and a source-side select gate line SGSB are connected to gate electrodes of the select transistors (STD, STS, STSB), respectively. The drain-side select gate line SGD is disposed corresponding to the string unit SU and is connected in common to all the memory strings MS in one string unit SU. The source-side select gate line SGS is connected in common to all the memory strings MS in the memory block BLK. The source-side select gate line SGSB is connected in common to all the memory strings MS in the memory block BLK. Hereinafter, the drain-side select gate line SGD, the source-side select gate line SGS, and the source-side select gate line SGSB are simply referred to as select gate lines (SGD, SGS, SGSB) or select gate lines (SGD, SGS) in some cases.

[Structure of Memory Cell Array MCA]

For example, as illustrated in FIG. 6, the memory cell array MCA is disposed above a semiconductor substrate 100. In the example in FIG. 6, between the semiconductor substrate 100 and the memory cell array MCA, a plurality of transistors Tr constituting the peripheral circuit PC are disposed.

For example, as illustrated in FIG. 6, FIG. 8, and FIG. 9, the plurality of memory blocks BLK arranged in the Y-direction are disposed in the memory cell array MCA. An inter-block insulating layer ST of silicon oxide (SiO₂) or the like is disposed between two memory blocks BLK mutually adjacent in the Y-direction. A plurality of string units SU are disposed between two inter-block insulating layers ST mutually adjacent in the Y-direction. An inter-string unit insulating layer SHE of silicon oxide (SiO₂) or the like is disposed between two string units SU mutually adjacent in the Y-direction.

Note that, for example, as exemplified in FIG. 8 and FIG. 9, in the following description, the plurality of string units SU in the memory block BLK are each referred to as string units SUa, SUb, SUc, SUd, SUe in some cases. The drain-side select gate lines SGD corresponding to the string units SUa, SUb, SUc, SUd, SUe are each referred to as drain-side select gate lines SGDa, SGDb, SGDc, SGDd, SGDe in some cases.

For example, as illustrated in FIG. 6, the memory block BLK include a plurality of conductive layers 110 arranged in the Z-direction, a plurality of semiconductor columns 120 extending in the Z-direction, and a respective plurality of gate insulating films 130 disposed between the plurality of conductive layers 110 and the plurality of semiconductor columns 120.

The conductive layer 110 is an approximately plate-shaped conductive layer extending in the X-direction. The conductive layer 110 may include, for example, a stacked film including a barrier conductive film, such as titanium nitride (TiN), and a metal film, such as tungsten (W). The conductive layer 110 may contain, for example, polycrystalline silicon containing impurities, such as phosphorus (P) or boron (B). Between the plurality of conductive layers 110 arranged in the Z-direction, insulating layers 101 of silicon oxide (SiO₂) or the like are disposed.

Among the plurality of conductive layers 110, two or more conductive layers 110 positioned at the lowermost layer function as the source-side select gate lines SGS, SGSB (FIG. 5) and gate electrodes of the plurality of source-side select transistors STS, STSB connected to these source-side select gate lines SGS, SGSB. These plurality of conductive layers 110 are electrically independent in every memory block BLK.

Additionally, a plurality of conductive layers 110 positioned above this conductive layer 110 function as the word lines WL (FIG. 5) and gate electrodes of the plurality of memory cells MC (FIG. 5) connected to the word lines WL. Each of these plurality of conductive layers 110 is electrically independent in every memory block BLK.

One or a plurality of conductive layers 110 positioned above them function as the drain-side select gate line SGD and gate electrodes of a plurality of the drain-side select transistors STD (FIG. 5) connected to the drain-side select gate line SGD. These plurality of conductive layers 110 have widths in the Y-direction smaller than those of the other conductive layers 110.

A semiconductor layer 112 is disposed below the conductive layers 110. The semiconductor layer 112 may contain, for example, polycrystalline silicon containing impurities, such as phosphorus (P) or boron (B). The insulating layer 101 of silicon oxide (SiO₂) or the like is disposed between the semiconductor layer 112 and the conductive layer 110.

The semiconductor layer 112 functions as the source line SL (FIG. 5). The source line SL is disposed in common, for example, for all the memory blocks BLK included in the memory cell array MCA.

For example, as illustrated in FIG. 6 and FIG. 8, the semiconductor columns 120 are arranged in the X-direction and the Y-direction in a predetermined pattern. The semiconductor columns 120 function as the channel regions of the plurality of memory cells MC and the select transistors (STD, STS, STSB) included in one memory string MS (FIG. 5). The semiconductor column 120 is, for example, a semiconductor layer of polycrystalline silicon (Si) or the like. For example, as illustrated in FIG. 6, the semiconductor column 120 has a substantially closed-bottomed cylindrical shape and includes an insulating layer 125 of silicon oxide or the like, in a center part. The semiconductor column 120 has an outer peripheral surface that is surrounded by the respective conductive layers 110 and is opposed to the conductive layers 110.

In an upper end portion of the semiconductor column 120, an impurity region 121 containing N-type impurities, such as phosphorus (P), is disposed. The impurity region 121 is connected to the bit line BL via a contact Ch and a contact Vy.

The gate insulating film 130 has a substantially closed-bottomed cylindrical shape that covers an outer peripheral surface of the semiconductor column 120. The gate insulating film 130 includes, for example, as illustrated in FIG. 7, a tunnel insulating film 131, an electric charge accumulating film 132, and a block insulating film 133, which are stacked between the semiconductor column 120 and the conductive layers 110. The tunnel insulating film 131 and the block insulating film 133 are, for example, insulating films of silicon oxide (SiO₂) or the like. The electric charge accumulating film 132 is, for example, a film of silicon nitride (Si₃N₄) that can accumulate electric charge. The tunnel insulating film 131, the electric charge accumulating film 132, and the block insulating film 133, which have substantially cylindrical shapes, extend in the Z-direction along the outer peripheral surface of the semiconductor column 120 excluding a contact portion between the semiconductor column 120 and the semiconductor layer 112.

The gate insulating film 130, for example, may include a floating gate, such as polycrystalline silicon, containing N-type or P-type impurities.

As illustrated in FIG. 6, a plurality of contacts CC are disposed at end portions in the X-direction of the plurality of conductive layers 110. The plurality of conductive layers 110 are connected to the peripheral circuit PC via these plurality of contacts CC. These plurality of contacts CC extend in the Z-direction and are connected to the conductive layers 110 at lower ends. The contact CC may include, for example, a stacked film including a barrier conductive film, such as titanium nitride (TiN), and a metal film, such as tungsten (W), or the like.

[Configuration of Peripheral Circuit PC]

For example, as illustrated in FIG. 4, the peripheral circuit PC includes row decoders RD0, RD1, which are connected to the memory cell arrays MCA0, MCA1, respectively, and sense amplifiers SA0, SA1. The peripheral circuit PC includes a voltage generation circuit VG and a sequencer SQC. The peripheral circuit PC includes an input/output control circuit I/O, a logic circuit CTR, an address register ADR, a command register CMR, and a status register STR. In the following description, the row decoders RD0, RD1 are referred to as a row decoder RD, and the sense amplifiers SA0, SA1 are referred to as a sense amplifier SA in some cases.

[Configuration of Row Decoder RD]

For example, as illustrated in FIG. 5, the row decoder RD (FIG. 4) includes an address decoder 22 decoding address data Add (FIG. 4). The row decoder RD (FIG. 4) includes a block select circuit 23 and a voltage select circuit 24 that transfer an operating voltage to the memory cell array MCA according to an output signal of the address decoder 22.

The address decoder 22 is connected to a plurality of block select lines BLKSEL_A, a plurality of block select lines BLKSEL_B, and a plurality of voltage select lines 33. For example, the address decoder 22 sequentially refers to a row address RA in the address register ADR (FIG. 4) in response to a control signal from the sequencer SQC.

In the illustrated example, in the address decoder 22, each one set of the block select lines BLKSEL_A, BLKSEL_B is disposed per the memory block BLK. However, this configuration is appropriately changeable. For example, each one set of the block select lines BLKSEL may be included in the two or more memory blocks BLK.

The block select circuit 23 includes a plurality of block selectors 34 corresponding to the memory blocks BLK. The block selectors 34 each include a block select circuit 34A and a block select circuit 34B.

The block select circuit 34A each include a plurality of block select transistors 35A corresponding to the word lines WL and the select gate lines (SGD, SGS, SGSB). The block select transistor 35A is, for example, a field-effect type high breakdown voltage transistor. The block select transistors 35A have respective drain electrodes electrically connected to the corresponding word line WL or the select gate line (SGD, SGS, SGSB). Source electrodes of the block select transistors 35A are each electrically connected to a voltage supply line 31 via a wiring CG and the voltage select circuit 24. Gate electrodes of the block select transistors 35A are connected in common to the corresponding block select line BLKSEL_A.

The block select circuits 34B each include a plurality of block select transistors 35B corresponding to a plurality of the drain-side select gate lines SGD in one memory block BLK. The block select transistor 35B is, for example, a field-effect type high breakdown voltage transistor. The block select transistors 35B have drain electrodes each electrically connected to the corresponding drain-side select gate line SGD. Source electrodes of the block select transistors 35B are each electrically connected to the voltage supply line 31 via the wiring CG and the voltage select circuit 24. Gate electrodes of the block select transistors 35B are connected in common to the corresponding block select line BLKSEL_B.

The voltage select circuit 24 includes a plurality of voltage selectors 36 corresponding to the word lines WL and the select gate lines (SGD, SGS, SGSB). Each of these plurality of voltage selectors 36 includes a plurality of voltage select transistors 37. The voltage select transistor 37 is, for example, a field-effect type high breakdown voltage transistor. The voltage select transistors 37 have drain terminals each electrically connected to the corresponding word line WL or the select gate line (SGD, SGS, SGSB) via the wiring CG and the block select circuit 23. Each of source terminals is electrically connected to the corresponding voltage supply line 31. Each of gate electrodes is connected to the corresponding voltage select line 33.

[Configuration of Sense Amplifier SA]

The sense amplifiers SA0, SA1 (FIG. 4) include sense amplifier modules SAM0, SAM1 and cache memories CM0, CM1 (data registers), respectively. The cache memories CM0, CM1 include latch circuits XDL0, XDL1, respectively.

In the following description, the sense amplifier modules SAM0, SAM1 are referred to as a sense amplifier module SAM, the cache memories CM0, CM1 are referred to as a cache memory CM, and the latch circuits XDL0, XDL1 are referred to as a latch circuit XDL in some cases.

[Circuit Configuration of Sense Amplifier Module SAM]

For example, as illustrated in FIG. 10, the sense amplifier module SAM (FIG. 4) includes a plurality of sense amplifier units SAU0 to SAU15. The plurality of sense amplifier units SAU0 to SAU15 correspond to the plurality of bit lines BL. The sense amplifier units SAU0 to SAU15 each include the sense amplifier SA, a wiring LBUS, latch circuits SDL and DL0 to DLn (n is a natural number). To the wiring LBUS, a charge transistor 55 (FIG. 11) for precharge is connected. The wiring LBUS is connected to a wiring DBUS via a switch transistor DSW. To the wiring DBUS, a charge transistor 61 for precharge is connected.

As illustrated in FIG. 11, the sense amplifier SA includes a sense transistor 41. The sense transistor 41 discharges electric charge of the wiring LBUS according to current flowing in the bit line BL. A source electrode of the sense transistor 41 is connected to a voltage supply line to which a ground voltage V_{SS} is applied. A drain electrode is connected to the wiring LBUS via a switch transistor 42. A gate electrode is connected to the bit line BL via a sense node SEN, a discharge transistor 43, a node COM, a clamp transistor 44, and a high breakdown voltage transistor 45. The sense node SEN is connected to an internal control signal line CLKSA via a capacitor 48.

The sense amplifier SA includes a voltage transfer circuit. The voltage transfer circuit selectively electrically conducts the node COM and the sense node SEN with a voltage supply line to which a voltage V_{DD} is applied or a voltage supply line to which a voltage Vsgc is applied according to data latched by the latch circuit SDL. The voltage transfer circuit includes a node N1, a charge transistor 46, a charge transistor 49, a charge transistor 47, and a discharge transistor 50. The charge transistor 46 is connected between the node N1 and the sense node SEN. The charge transistor 49 is connected between the node N1 and the node COM. The charge transistor 47 is connected between the node N1 and the voltage supply line to which the voltage V_{DD} is applied. The discharge transistor 50 is connected between the node N1 and the voltage supply line to which the voltage V_{SRC} is applied. The charge transistor 47 and the discharge transistor 50 include gate electrodes connected in common to a node INV_S of the latch circuit SDL.

The sense transistor 41, the switch transistor 42, the discharge transistor 43, the clamp transistor 44, the charge transistor 46, the charge transistor 49, and the discharge transistor 50 are, for example, enhancement type NMOS transistors. The high breakdown voltage transistor 45 is, for example, a depletion type NMOS transistor. The charge transistor 47 is, for example, a PMOS transistor.

The switch transistor 42 has a gate electrode connected to a signal line STB. The discharge transistor 43 has a gate electrode connected to a signal line XXL. The clamp transistor 44 has a gate electrode connected to a signal line BLC. The high breakdown voltage transistor 45 has a gate electrode connected to a signal line BLS. The charge transistor 46 has a gate electrode connected to a signal line HLL. The charge transistor 49 has a gate electrode connected to a signal line BLX. These signal lines STB, XXL, BLC, BLS, HLL, BLX are connected to the sequencer SQC.

As illustrated in FIG. 11, the latch circuit SDL includes nodes LAT_S, INV_S, an inverter 51, an inverter 52, a switch transistor 53, and a switch transistor 54. The inverter 51 includes an output terminal connected to the node LAT_S and an input terminal connected to the node INV_S. The inverter 52 includes an input terminal connected to the node LAT_S and an output terminal connected to the node INV_S. The switch transistor 53 is disposed in a current path between the node LAT_S and the wiring LBUS. The switch transistor 54 is disposed in a current path between the node INV_S and the wiring LBUS. The switch transistors 53, 54 are, for example, NMOS transistors. The switch transistor 53 has a gate electrode connected to the sequencer SQC via a signal line STL. The switch transistor 54 has a gate electrode connected to the sequencer SQC via a signal line STI.

The latch circuits DL0 to DLn are configured almost similarly to the latch circuit SDL. However, as described above, the node INV_S of the latch circuit SDL is electrically conductive to gate electrodes of the charge transistor 47 and the discharge transistor 50 in the sense amplifier SA. In this respect, the latch circuits DL0 to DLn are different from the latch circuit SDL.

The switch transistor DSW is, for example, an NMOS transistor. The switch transistor DSW is connected between the wiring LBUS and the wiring DBUS. The switch transistor DSW has a gate electrode connected to the sequencer SQC via a signal line DBS (FIG. 10).

As exemplified in FIG. 10, the above-described signal lines STB, HLL, XXL, BLX, BLC, BLS are each connected between all the sense amplifier units SAU included in the sense amplifier module SAM in common. The voltage supply line to which the voltage V_{DD} is applied and the voltage supply line to which the voltage V_{SRC} is applied described above are each connected between all the sense amplifier units SAU included in the sense amplifier module SAM in common. The signal line STI and the signal line STL of the latch circuit SDL are each connected between all the sense amplifier units SAU included in the sense amplifier module SAM in common. Similarly, signal lines TIO to TIn, TLO to TLn corresponding to the signal lines STI and the signal lines STL in the latch circuits DL0 to DLn are each connected between all the sense amplifier units SAU included in the sense amplifier module SAM in common. Meanwhile, a plurality of the above-described signal lines DBS are disposed corresponding to all the respective sense amplifier units SAU included in the sense amplifier module SAM.

The cache memory CM includes a plurality of the latch circuits XDL. The plurality of latch circuits XDL are each connected to a latch circuit in the sense amplifier module SAM. In the latch circuit XDL, for example, user data written to the memory cell MC or user data read from the memory cell MC is stored.

For example, a column decoder is connected to the cache memory CM. The column decoder decodes a column address CA stored in the address register ADR (FIG. 4) and selects the latch circuit XDL corresponding to the column address CA.

At a write operation, user data Dat included in these plurality of latch circuits XDL are sequentially transferred to the latch circuits in the sense amplifier modules SAM. At a read operation, the user data Dat included in the latch circuits in the sense amplifier modules SAM are sequentially transferred to the latch circuits XDL. At a data-out operation, the user data Dat included in the latch circuits XDL are sequentially transferred to the input/output control circuit I/O.

[Configuration of Voltage Generation Circuit VG]

For example, as illustrated in FIG. 5, the voltage generation circuit VG (FIG. 4) is connected to a plurality of the voltage supply lines 31. The voltage generation circuit VG includes, for example, a step down circuit, such as a regulator, and a step up circuit, such as a charge pump circuit 32. These step down circuit and step up circuit are each connected to the voltage supply line to which a power supply voltage V_{CC} or the ground voltage V_{SS} (FIG. 4) is applied. These voltage supply lines are connected to, for example, the pad electrodes P described with reference to FIG. 2 and FIG. 3. For example, the voltage generation circuit VG generates a plurality of operating voltages applied to the bit line BL, the source line SL, the word line WL, and the select gate lines (SGD, SGS, SGSB) in the read operation, the write operation, and the erase operation on the memory cell array MCA in response to the control signal from the sequencer SQC to simultaneously output the operating voltages to the plurality of voltage supply lines 31. The operating voltage output from the voltage supply line 31 is appropriately adjusted in response to the control signal from the sequencer SQC.

[Configuration of Sequencer SQC]

In accordance with command data Cmd stored in the command register CMR, the sequencer SQC (FIG. 4) outputs an internal control signal to the row decoders RD0, RD1, the sense amplifier modules SAM0, SAM1, and the voltage generation circuit VG. The sequencer SQC appropriately outputs status data Stt indicative of a state of the memory die MD to the status register STR.

The sequencer SQC generates a ready/busy signal and outputs it to a terminal RY//BY. In a period while the terminal RY//BY is in an “L” state (busy period), access to the memory die MD is basically inhibited. In a period while the terminal RY//BY is in an “H” state (a ready period), access to the memory die MD is permitted. Note that, for example, the terminal RY//BY is achieved by the pad electrode P described with reference to FIG. 2 and FIG. 3.

[Configuration of Address Register ADR]

As illustrated in FIG. 4, the address register ADR is connected to the input/output control circuit I/O and stores the address data Add input from the input/output control circuit I/O. For example, the address register ADR includes a plurality of 8-bit register strings. For example, when an internal operation, such as the read operation, the write operation, or the erase operation, is performed, the register string latches the address data Add corresponding to the internal operation in execution.

The address data Add, for example, includes the column address CA (FIG. 4) and the row address RA (FIG. 4). For example, the row address RA includes a block address to identify the memory block BLK (FIG. 5), a page address to identify the string unit SU and the word line WL, a plane address to identify the memory cell array MCA (plane), and a chip address to identify the memory die MD.

[Configuration of Command Register CMR]

The command register CMR is connected to the input/output control circuit I/O and stores the command data Cmd input from the input/output control circuit I/O. For example, the command register CMR includes at least one set of an 8-bit register string. When the command data Cmd is stored in the command register CMR, the control signal is transmitted to the sequencer SQC.

[Configuration of Status Register SIR]

The status register STR is connected to the input/output control circuit I/O and stores the status data Stt output to the input/output control circuit I/O. For example, the status register STR includes a plurality of 8-bit register strings. For example, when the internal operation, such as the read operation, the write operation, or the erase operation, is performed, the register string latches the status data Stt regarding the internal operation in execution. The register string, for example, latches ready/busy information of the memory cell arrays MCA0, MCA1.

[Configuration of Input/Output Control Circuit I/O]

The input/output control circuit I/O (FIG. 4) includes data signal input/output terminals DQ0 to DQ7, data strobe signal input/output terminals DQS, /DQS, a shift register, and a buffer circuit.

Each of the data signal input/output terminals DQ0 to DQ7 and the data strobe signal input/output terminals DQS, /DQS is achieved by, for example, the pad electrodes P described with reference to FIG. 2 and FIG. 3. The data input via the data signal input/output terminals DQ0 to DQ7 is input to the cache memory CM, the address register ADR, or the command register CMR from the buffer circuit in response to the internal control signal from the logic circuit CTR. The data output via the data signal input/output terminals DQ0 to DQ7 is input to the buffer circuit from the cache memory CM or the status register STR in response to the internal control signal from the logic circuit CTR.

Signals input via the data strobe signal input/output terminals DQS, /DQS (for example, a data strobe signal and its complementary signal) are used at data input via the data signal input/output terminals DQ0 to DQ7. The data input via the data signal input/output terminals DQ0 to DQ7 are taken in the shift register in the input/output control circuit I/O at a timing of a voltage rise edge (switching of the input signal) of the data strobe signal input/output terminal DQS and a voltage fall edge (switching of the input signal) of the data strobe signal input/output terminal/DQS, and at a timing of a voltage fall edge (switching of the input signal) of the data strobe signal input/output terminal DQS and a voltage rise edge (switching of the input signal) of the data strobe signal input/output terminal/DQS.

[Configuration of Logic Circuit CTR]

The logic circuit CTR (FIG. 4) includes a plurality of external control terminals/CE, CLE, ALE, /WE, /RE, RE and a logic circuit connected to these plurality of external control terminals/CE, CLE, ALE, /WE, /RE, RE. The logic circuit CTR receives an external control signal from the controller die CD via the external control terminals/CE, CLE, ALE, /WE, /RE, RE and outputs the internal control signal to the input/output control circuit I/O in response to the external control signal.

Note that, for example, each of the external control terminals/CE, CLE, ALE, /WE, /RE, RE is achieved by the pad electrode P described with reference to FIG. 2 and FIG. 3.

[Operation]

Next, the operation of the semiconductor memory device according to the embodiment is described.

[Read Operation]

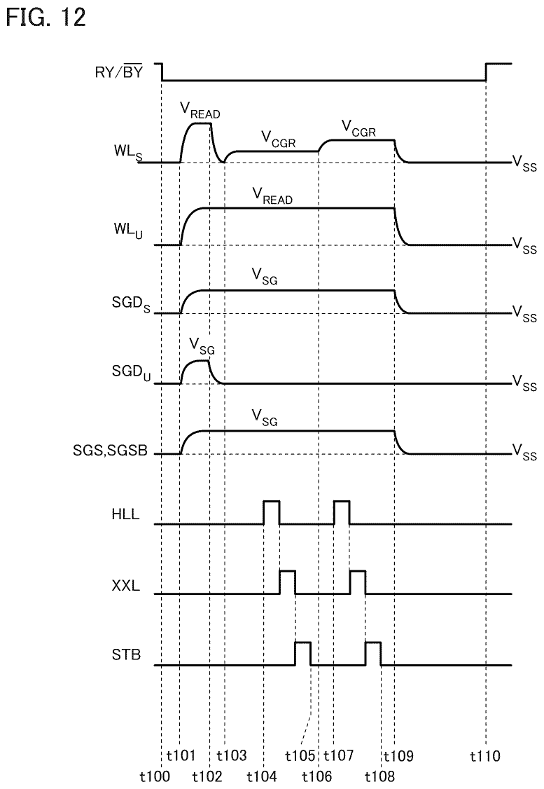

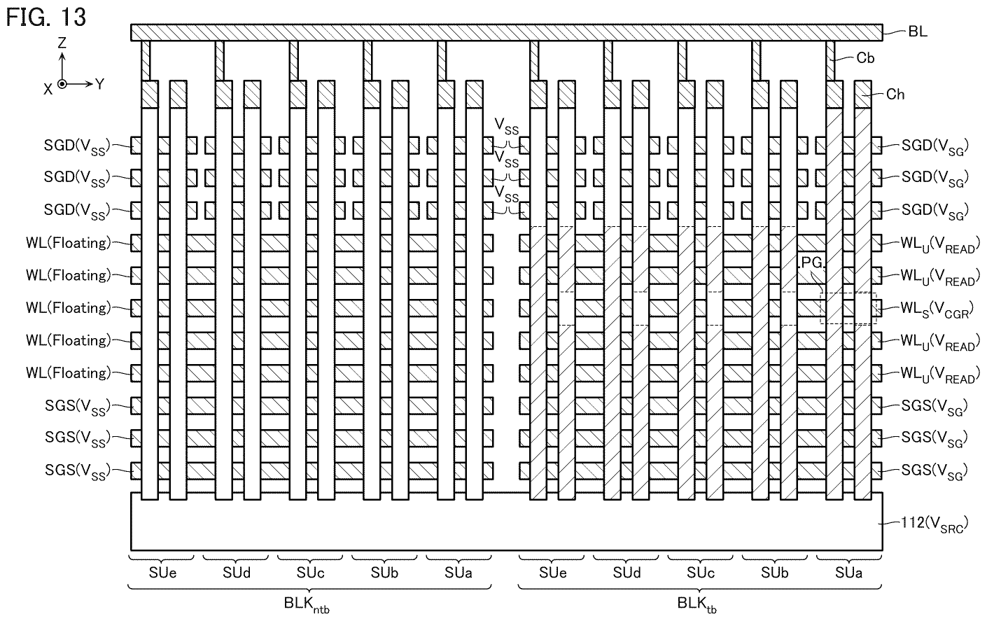

The read operation of the memory die MD according to the embodiment is described. FIG. 12 is a timing chart for describing the read operation. FIG. 13 is a schematic cross-sectional view for describing the read operation.

In the following description, a drain-side select gate line SGD corresponding to the string unit SU (FIG. 13) as an operation target is referred to as a drain-side select gate line SGD_{S}, and other drain-side select gate lines SGD corresponding to the string units SU are referred to as drain-side select gate lines SGD_{U} in some cases. A word line WL as an operation target is referred to as a selected word line WL_{S}, and other word lines WL are referred to as unselected word lines WL_{U} in some cases. In the following description, an example of performing the read operation on one connected to the selected word line WL s (hereinafter referred to as a “selected memory cell MC” in some cases) among the plurality of memory cells MC included in the string unit SU (FIG. 13) as an operation target is described. In the following description, a configuration including such a plurality of the selected memory cells MC is referred to as a selected page PG in some cases. Additionally, a memory block BLK including the selected page PG is referred to as a select memory block BLK_{tb} and other memory blocks BLK are referred to as unselected memory blocks BLK_{ntb} in some cases.

The select transistors (STS, STSB) are simply referred to as a source-side select transistor STS and the select gate lines (SGS, SGSB) are simply referred to as the source-side select gate line SGS in some cases.

In the following description, a description is given of an example in which each of the memory cells MC stores a plurality of bits of data and a plurality of read voltages are used in the read operation.

At timing t100 of the read operation, the controller die CD sequentially inputs the command data Cmd and the address data Add instructing the read operation to the memory die MD. Thus, the terminal RY//BY enters a period in an “L” state (busy period).

At timing t101, for example, as illustrated in FIG. 12, a voltage V_{SG} is applied to the drain-side select gate line SGD_{S}, the drain-side select gate line SGD_{U}, and the source-side select gate line SGS of the select memory block BLK_{tb} to turn all the select transistors (STD, STS) in an ON state. Read pass voltage V_{READ} is applied to the select word line WL_{S} and the non-select word lines WL_{U} to turn all the memory cells MC in an ON state.

At timing t102, for example, as illustrated in FIG. 12 and FIG. 13, the read pass voltage V_{READ} is applied to the non-select word line WL_{U} of the select memory block BLK_{tb} to turn the memory cell MC connected to the non-select word line WL_{U} in an ON state. Meanwhile, the ground voltage V_{SS} is applied to the select word line WL_{S} to turn the memory cell MC connected to the select word line WL_{S} in an OFF state. The voltage V_{SG} is applied to the drain-side select gate line SGD_{S} and the source-side select gate line SGS of the string unit SUa including the selected page PG to turn the select transistors STD, STS connected to the drain-side select gate line SGD_{S} and the source-side select gate line SGS in an ON state. The ground voltage V_{SS} is applied to the drain-side select gate lines SGD_{U} of the string units SUb to SUe not including the selected page PG to turn the select transistors STD connected to the drain-side select gate lines SGD_{U} in an OFF state.

As illustrated in FIG. 13, the word line WL of the unselected memory block BLK_{ntb} is turned to a floating state. The ground voltage V_{SS} is applied to the select gate lines (SGD, SGS) of the unselected memory block BLK_{ntb} and the select transistors (STD, STS) connected to the select gate lines (SGD, SGS) are turned to an OFF state.

At timing t103, a predetermined read voltage V_{CGR} is applied to the select word line WL_{S} of the select memory block BLK_{tb}. Thus, the select memory cell MC included in the selected page PG turns to an ON state or an OFF state according to each threshold voltage. That is, a part of the select memory cells MC of a part of the selected page PG turns to an ON state, and the remaining select memory cells MC turn to an OFF state.

At timing t104 to timing t105 of the read operation, for example, the bit lines BL are charged. For example, the latch circuit SDL in FIG. 11 is caused to latch “H” to set states of the signal lines STB, XXL, BLC, BLS, HLL, BLX to “L, L, H, H, H, H”, respectively. Thus, the voltage V_{DD} is applied to the bit lines BL and the sense node SEN, and charging of the bit lines BL and the sense node SEN starts. For example, the voltage V_{SRC} is applied to the source line SL (FIG. 5) to start charging them. The voltage V_{SRC}, for example, has about the same magnitude as a magnitude of the ground voltage V_{SS}. The voltage V_{SRC} may be a voltage, for example, slightly larger than the ground voltage V_{SS} and sufficiently smaller than the voltage V_{DD}.

Subsequently, the sense amplifier module SAM (FIG. 4) performs a sense operation that detects the ON state/OFF state of the memory cell MC to acquire data indicative of the state of this memory cell MC. For example, in a state where a predetermined bit line voltage is applied to the bit line BL (FIG. 11), a state of the signal line XXL is set to “H” and a sense node of the sense amplifier SA (FIG. 11) is electrically conducted with the bit line BL for a certain period. After performing the sense operation, a state of the signal line STB is set to “H” and the sense transistor is electrically conducted with the wiring LBUS (FIG. 11). Thus, electric charge of the wiring LBUS is discharged or maintained. Any of the latch circuits in the sense amplifier unit SAU electrically conducts with the wiring LBUS and data of the wiring LBUS is latched by this latch circuit.

At timing t106 of the read operation, another read voltage V_{CGR} is applied to the select word line WL_{S} of the select memory block BLK_{tb}. Thus, a part of the select memory cells MC of a part of the selected pages PG turns to an ON state, and the remaining select memory cells MC turn to an OFF state.

At timing t107 to timing t108 of the read operation, similarly to timing t104 to timing t105, the sense operation is performed by the sense amplifier module SAM and data indicative of the state of this memory cell MC is acquired.

At timing t109 of the read operation, the ground voltage V_{SS} is applied to the select word line WL_{S}, the non-select word line WL_{U}, and the select gate lines (SGD, SGS) of the select memory block BLK_{tb}.

Note that in the read operation, arithmetic processing, such as AND and OR, is performed on the data indicative of the state of the above-described memory cell MC, and thus, the data stored in the memory cell MC is calculated. This data is transferred to the cache memory CM (FIG. 4) via the wiring LBUS (FIG. 10), the switch transistor DSW, and the wiring DBUS.

[Write Operation]

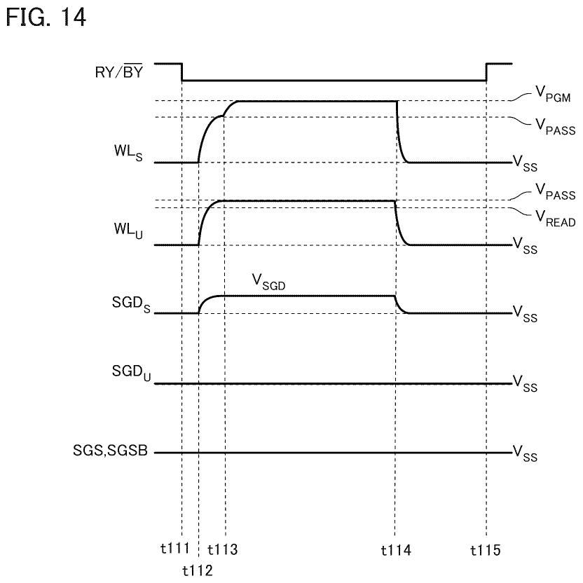

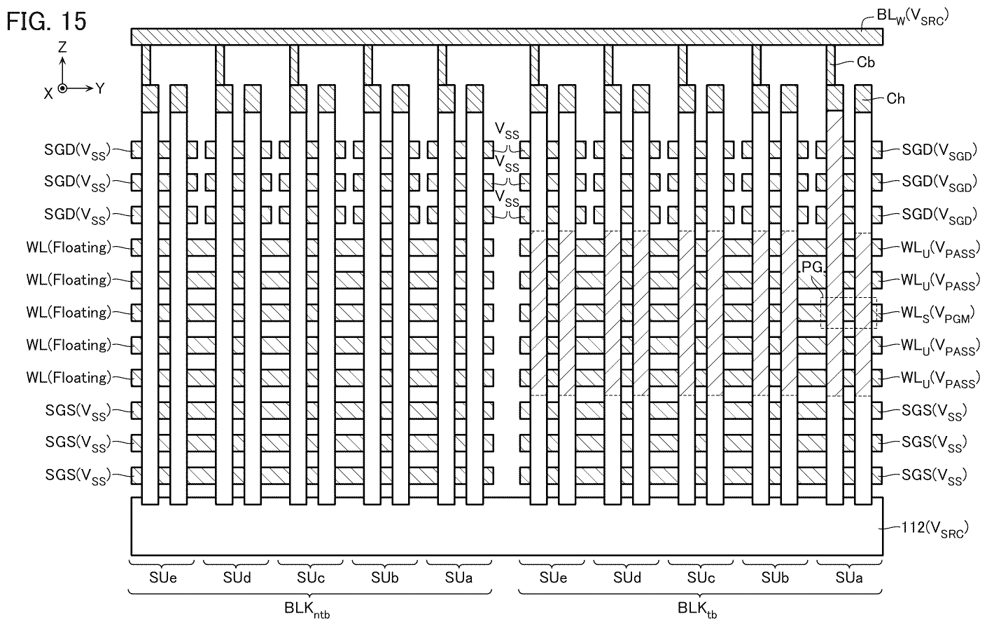

Next, the write operation of the memory die MD according to the embodiment is described. FIG. 14 is a timing chart for describing the write operation. FIG. 15 is a schematic cross-sectional view for describing the write operation.

In the following description, an example in which the write operation is performed on the plurality of selected memory cells MC corresponding to the selected page PG is described. In the following description, a memory block BLK target for the write operation is referred to as the select memory block BLK_{tb} and other memory blocks BLK are referred to as the unselected memory block BLK_{ntb} in some cases.

At timing t111 of the write operation, the controller die CD sequentially inputs the command data Cmd and the address data Add instructing the write operation to the memory die MD. Thus, the terminal RY//BY enters a period in an “L” state (busy period).

At timings t111 to t112, for example, the voltage V_{SRC} is applied to the bit line BL_{W} (FIG. 15) connected to one that adjusts the threshold voltage among the plurality of select memory cells MC and applies the voltage V_{DD} to a bit line BL_{P} connected to one that does not adjust the threshold voltage among the plurality of select memory cells MC. The voltage V_{SRC} is applied to the source line SL (semiconductor layer 112).

For example, “L” is latched to the latch circuit SDL (FIG. 11) corresponding to the bit line BL_{W} and “H” is latched to the latch circuit SDL (FIG. 11) corresponding to the bit line BL_{P}. Additionally, the states of the signal lines STB, XXL, BLC, BLS, HLL, BLX are set to “L, L, H, H, L, H”, respectively. Hereinafter, one that adjusts the threshold voltage is referred to as a “write memory cell MC” and one that does not adjust the threshold voltage is referred to as an “inhibited memory cell MC” among the plurality of select memory cells MC in some cases.

At timing t112, a write pass voltage V_{PASS} is applied to the select word line WL_{S} and the non-select word line WL_{U} of the select memory block BLK_{tb}. A voltage V_{SGB} is applied to the drain-side select gate line SGD_{S} of the string unit SUa including the selected page PG in the select memory block BLK_{tb}. The write pass voltage V_{PASS} may have about the same magnitude as a magnitude of the read pass voltage \TREAD described with reference to FIG. 12 or may be larger than the read pass voltage \TREAD. The voltage V_{SGB} is smaller than the voltage V_{SG} described with reference to FIG. 12 and has a magnitude to the extent that the drain-side select transistor STD turns to an ON state or an OFF state according to the voltage of the bit line BL. The ground voltage V_{SS} is applied to the drain-side select gate lines SGD_{U} and the source-side select gate lines SGS of the string units SUb to SUe not including the selected page PG of the select memory block BLK_{tb} and the select transistors (STD, STS) connected to the drain-side select gate lines SGD_{U} and the source-side select gate lines SGS are set to an OFF state.

As illustrated in FIG. 15, the word line WL of the unselected memory block BLK_{ntb} is turned to a floating state. The ground voltage V_{SS} is applied to the select gate lines (SGD, SGS) of the unselected memory block BLK_{ntb} and the select transistors (STD, STS) connected to the select gate lines (SGD, SGS) are set to an OFF state.

At timing t113, a program voltage VPGM is applied to the select word line WL_{S} of the select memory block BLK_{tb}. The program voltage VPGM is larger than the write pass voltage V_{PASS}.

Here, for example, as illustrated in FIG. 15, the voltage V_{SRG} is applied from the bit line BL to the channel of the semiconductor column 120 connected to the bit line B_{LW}. A comparatively large electric field is generated between the semiconductor column 120 and the selected word line WL_{S}. This causes electrons in the channel of the semiconductor column 120 to tunnel into the electric charge accumulating film 132 (FIG. 7) via the tunnel insulating film 131 (FIG. 7). This increases a threshold voltage of the write memory cell MC.

Additionally, the channel of the semiconductor column 120 connected to the bit line BL P is in an electrically floating state, and this channel voltage is increased up to approximately the write pass voltage V_{PASS} by capacitive coupling with the unselected word line WL_{U}. Between such a semiconductor column 120 and the selected word line WL_{S}, only an electric field smaller than all of the above-described electric fields is generated. Accordingly, the electrons in the channel of the semiconductor column 120 do not tunnel into the electric charge accumulating film 132 (FIG. 7). Accordingly, the threshold voltage of the inhibited memory cell MC does not increase.

At timing t114, the ground voltage V_{SS} is applied to the select word line WL_{S}, the non-select word line WL_{U}, and the select gate lines (SGD, SGS).

[Erase Operation]

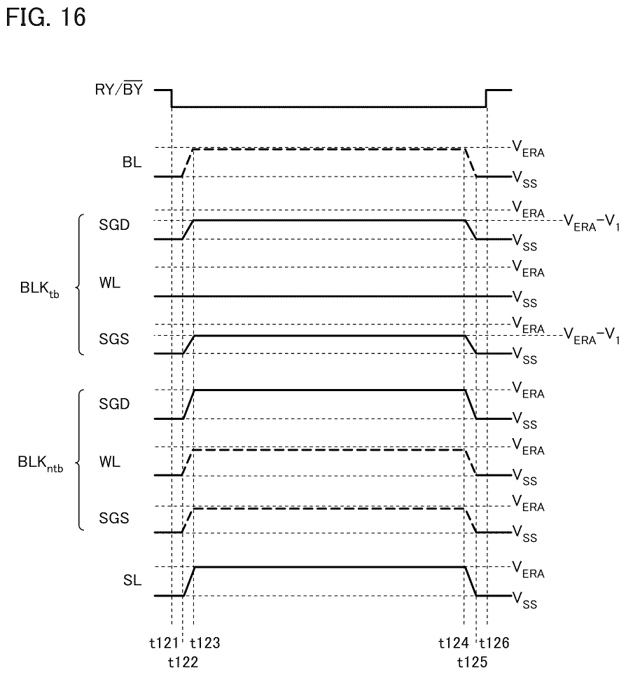

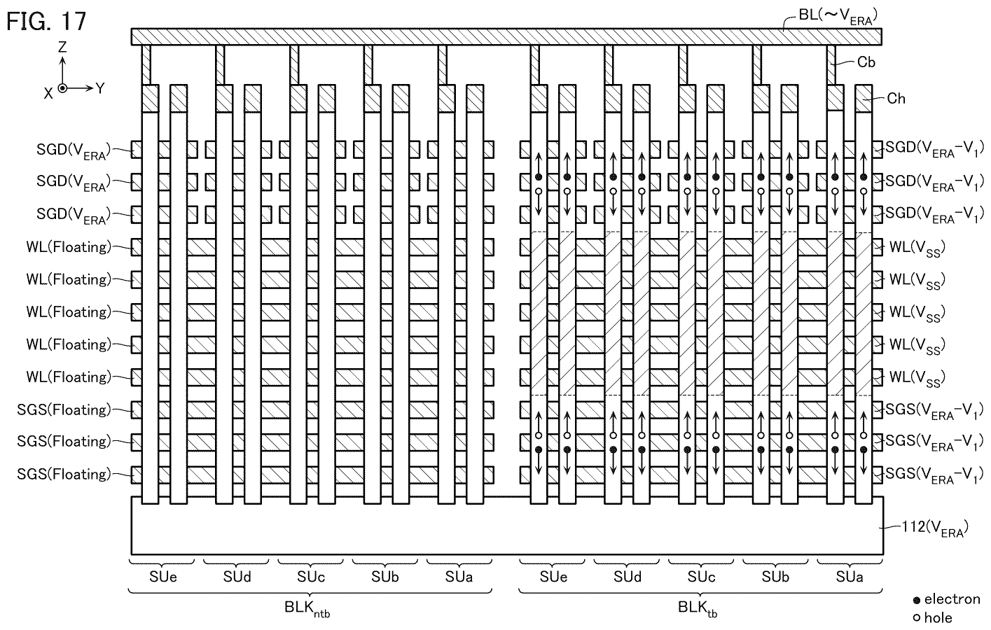

Next, the erase operation of the memory die MD according to the embodiment is described. FIG. 16 is a timing chart for describing the erase operation. FIG. 17 is a schematic cross-sectional view for describing the erase operation.

In the following description, a memory block BLK target for the erase operation is referred to as the select memory block BLK_{tb} and other memory blocks BLK are referred to as the unselected memory blocks BLK_{ntb} in some cases.

At timing t121 of the erase operation, the controller die CD sequentially inputs the command data Cmd and the address data Add instructing the erase operation to the memory die MD. Thus, the terminal RY//BY enters a period in an “L” state (busy period).

At timing t122 of the erase operation, for example, as illustrated in FIG. 16 and FIG. 17, the bit line BL is set to the floating state. Additionally, in the select memory block BLK_{tb}, a voltage V_{ERA}−V₁ is applied to the respective select gate lines (SGD, SGS) and the ground voltage V_{SS} is applied to the word line WL. The voltage V_{ERA}−V₁ applied to the select gate lines (SGD, SGS) of the select memory block BLK_{tb} is larger than the ground voltage V_{SS} applied to the word line WL. Additionally, in the unselected memory block BLK_{ntb}, the voltage V_{ERA} is applied to the drain-side select gate line SGD and the word line WL and the source-side select gate line SGS are set to the floating state. The voltage V_{ERA} is applied to the source line SL (semiconductor layer 112). The voltage V_{ERA} applied to the drain-side select gate line SGD of the unselected memory block BLK_{ntb} is larger than the voltage V_{ERA}−V₁ applied to the drain-side select gate line SGD of the select memory block BLK_{tb}.

At timing t122 of the erase operation, the voltage applied to the drain-side select gate line SGD of the unselected memory block BLK_{ntb} may be larger than the voltage V_{ERA} applied to the source line SL.

In the structure in the embodiment, when the voltage V_{ERA} is applied to the drain-side select gate line SGD of the unselected memory block BLK_{ntb}, by capacitive coupling between the gate electrode and the channel region of the drain-side select transistor STD, a voltage of a channel region of the drain-side select transistor STD of the unselected memory block BLK_{ntb} increases. In association with this, as illustrated in FIG. 16, at timing t123 of the erase operation, the voltage of the bit line BL in the floating state increases to a value that is the same as the voltage V_{ERA} or close to the voltage V_{ERA}.

From timing t123 to timing t124, by Gate Induced Drain Leakage (GIDL) described later, data written to the memory cell MC is erased.

At timing t124, the ground voltage V_{SS} is applied to the select gate lines (SGD, SGS) and the word lines WL of the select memory block BLK_{tb} and the unselected memory block BLK_{ntb}.

[Erase Operation by GIDL]

At timing t123 to timing t124 of FIG. 16, as illustrated in FIG. 17, via the select gate lines (SGD, SGS) of the select memory block BLK_{tb}, the voltage V_{ERA}−V₁ is applied to the gate electrodes of the select transistors (STD, STS) of the select memory block BLK_{tb}. Via the bit line BL and the source line SL, the voltage V_{ERA} is applied to the channel regions of the select transistors (STD, STS) of the select memory block BLK_{tb}. Accordingly, a voltage V₁ is applied between the gate electrodes and the channel regions of the select transistors (STD, STS).

The voltage V₁ is, for example, a voltage having a magnitude to the extent that GIDL occurs at or near the channels (a surface of the semiconductor column 120) of the select transistors (STD, STS). By GIDL, for example, as illustrated in FIG. 17, electron-hole pairs occur at or near the channel of each of the select transistors (STD, STS).

Electrons generated in the drain-side select transistor STD are supplied to a bit line BL side, and the holes are supplied to a memory cell MC side. Electrons generated in the source-side select transistor STS are supplied to a source line SL side, and holes are supplied to the memory cell MC side. In association with this, the holes are accumulated on the channel region of the memory cell MC, and the voltage of the channel region of the memory cell MC increases.

At timing t123 to timing t124 of FIG. 16, the ground voltage V_{SS} is applied to the word line WL of the select memory block BLK_{tb}. Therefore, between the gate electrode and the channel region of the memory cell MC, a voltage around the voltage V_{ERA} is applied. This voltage has a magnitude to the extent that holes supplied by GIDL can tunnel the tunnel insulating film 131 and reach the electric charge accumulating film 132.

Thus, by accumulating the holes generated by the GIDL on the electric charge accumulating films 132 (FIG. 7) of all the memory cells MC included in the select memory block BLK_{tb}, threshold voltage of the memory cell MC is reduced to erase data in the memory cell MC.

[Operations of Row Decoder RD During Read, Write, and Erase Operations]

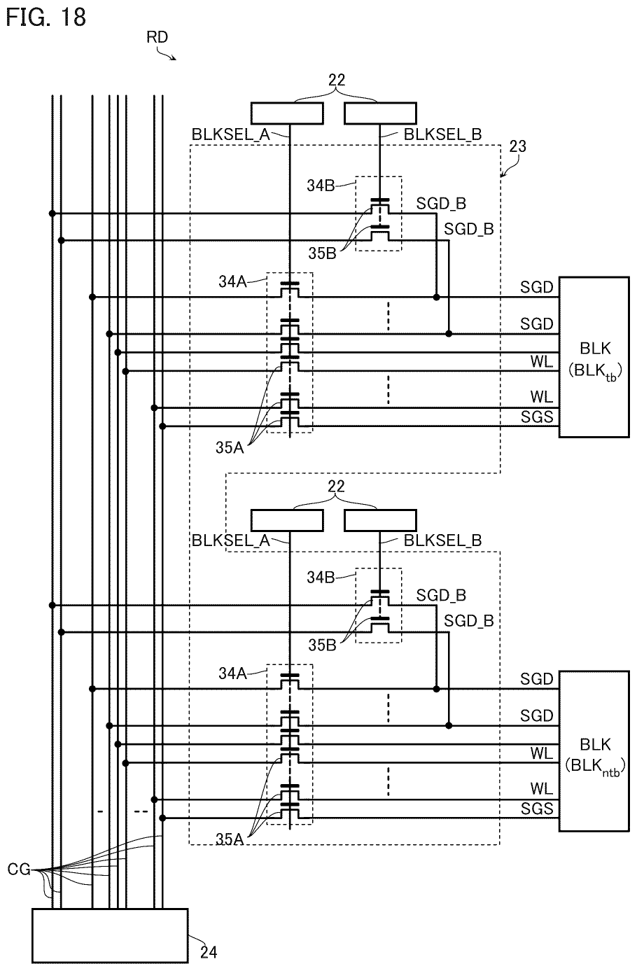

Next, with reference to FIG. 18, the operations of the row decoder RD during the read, write, and erase operations are described.

During the read operation and the write operation, the address decoder 22 sets a voltage of the block select line BLKSEL_A corresponding to the select memory block BLK_{tb} to an “H” state and sets a voltage of the block select line BLKSEL_A corresponding to the unselected memory block BLK_{ntb} to an “L” state. Thus, the plurality of block select transistors 35A included in the block select circuit 34A corresponding to the select memory block BLK_{tb} are set to an ON state. The plurality of block select transistors 35A included in the block select circuit 34A corresponding to the unselected memory block BLK_{ntb} are set to an OFF state.

The address decoder 22 sets voltages of the block select lines BLKSEL_B corresponding to the select memory block BLK_{tb} and the unselected memory block BLK_{ntb} to an “L” state. Thus, the plurality of block select transistors 35B included in the block select circuits 34B corresponding to the select memory block BLK_{tb} and the unselected memory block BLK_{ntb} are set to an OFF state.

Thus, in the select memory block BLK_{tb}, via the wiring CG and the block select transistor 35A, the above-described voltages required for the read and write operations are applied to the select gate lines (SGD, SGS) and the word line WL.

In the unselected memory block BLK_{ntb}, the select gate lines (SGD, SGS) and the word line WL enter the floating state. To the select gate lines (SGD, SGS) of the unselected memory block BLK_{ntb}, the ground voltage V_{SS} may be applied via an unillustrated wiring.

In the erase operation, the address decoder 22 performs operations similar to the operations during the read operation and the write operation on the block select line BLKSEL_A.

On the other hand, the address decoder 22 performs operations different from during the read operation and the write operation on the block select line BLKSEL_B. That is, the address decoder 22 sets a voltage of the block select line BLKSEL_B corresponding to the select memory block BLK_{tb} to an “L” state and a voltage of the block select line BLKSEL_B corresponding to the unselected memory block BLK_{ntb} to an “H” state. Thus, the plurality of block select transistors 35B included in the block select circuit 34B corresponding to the select memory block BLK_{tb} are set to an OFF state. The plurality of block select transistors 35B included in the block select circuit 34B corresponding to the unselected memory block BLK_{ntb} are set to an ON state.

Thus, in the select memory block BLK_{tb}, via the wiring CG and the block select transistor 35A, the above-described voltage required for the erase operation is applied to the select gate lines (SGD, SGS) and the word line WL.

On the other hand, to the drain-side select gate line SGD of the unselected memory block BLK_{ntb}, the above-described voltage V_{ERA} required for the erase operation is applied via the wiring CG and the block select transistor 35B.

### Comparative Example

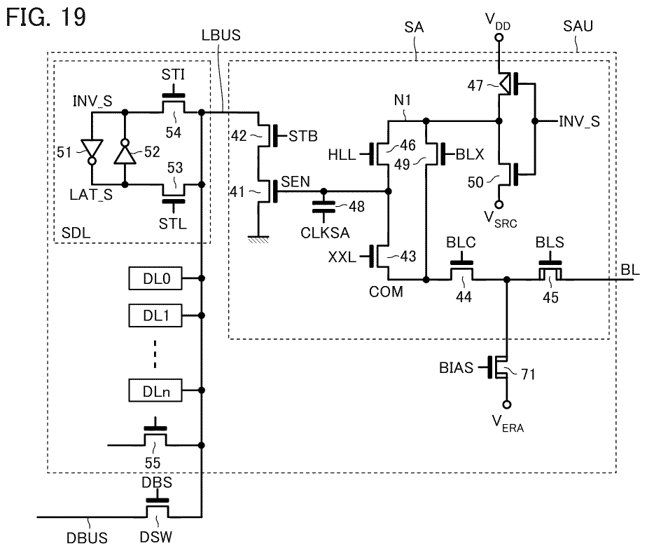

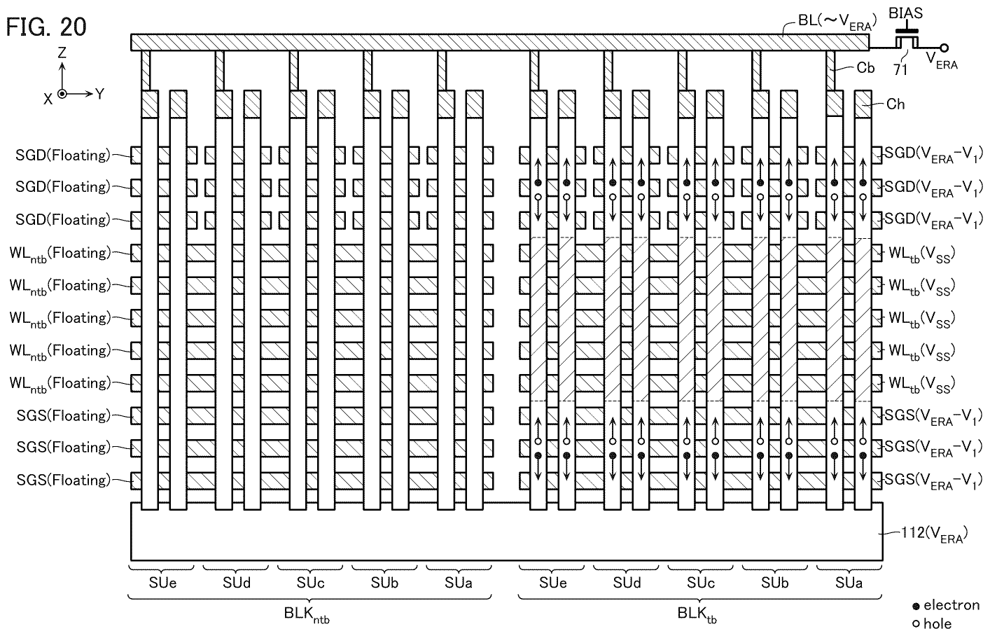

FIG. 19 is a schematic circuit diagram illustrating a configuration of a part of a semiconductor memory device according to the comparative example. FIG. 20 is a schematic cross-sectional view for describing an erase operation of the semiconductor memory device according to the comparative example.

The semiconductor memory device according to the comparative example is configured basically similarly to the semiconductor memory device according to the first embodiment. However, in the semiconductor memory device according to the comparative example, the sense amplifier unit SAU includes a high breakdown voltage transistor 71 (FIG. 19). The high breakdown voltage transistor 71 has a gate electrode connected to a signal line BIAS, a source terminal connected to a voltage supply line to which the voltage V_{ERA} is applied, and a drain terminal connected to the bit line BL via the high breakdown voltage transistor 45.

In the erase operation of the semiconductor memory device according to the comparative example, the voltage V_{ERA} required for the erase operation is generated in the voltage generation circuit VG and applied to the bit line BL via the voltage supply line and the high breakdown voltage transistor 71.

Here, in the erase operation by GIDL, as described above, the electrons generated in the drain-side select transistor STD are supplied to the bit line BL side. Here, when the electrons accumulate on the bit line BL, these electrons decrease the voltage of the bit line BL. When the voltage of the bit line BL decreases, the voltage of the channel region of the drain-side select transistor STD also decreases, a voltage difference between the channel region and the gate electrode of the drain-side select transistor STD decreases, and GIDL does not occur. To hold the voltage of the bit line BL to a value close to voltage V_{ERA} and keep generating GIDL, during the erase operation, it is necessary to continue applying the voltage V_{ERA} from a voltage source. In view of this, in the semiconductor memory device according to the comparative example, each of the bit lines BL is connected to the voltage supply line via the high breakdown voltage transistor 71.

However, since the voltage V_{ERA} is a comparatively high voltage, the high breakdown voltage transistor 71 designed to especially have a large gate length needs to be disposed. When the large-area high breakdown voltage transistors 71 are disposed in the sense amplifier unit SAU by the number of bit lines BL, there is a case where the circuit area is substantially increased.

[Effects]

The semiconductor memory device according to the embodiment applies the voltage V_{ERA} to at least one of the drain-side select gate lines SGD, SGDT of the unselected memory block BLK_{ntb} during the erase operation. By capacitive coupling between the drain-side select gate lines SGD, SGDT and an upper end portion of the semiconductor column 120, the voltages of the upper end portion of the semiconductor column 120 and the bit line BL connected to the upper end portion of the semiconductor column 120 boost up to near the voltage V_{ERA}. This method allows boosting the voltage of the bit line BL without connecting the bit line BL to the voltage generation circuit VG. Therefore, the high breakdown voltage transistors 71 can be omitted from the sense amplifier unit SAU. Accordingly, the stable erase operation can be performed without an increase in the circuit area. This allows achieving high integration of the semiconductor memory device.

### Modifications

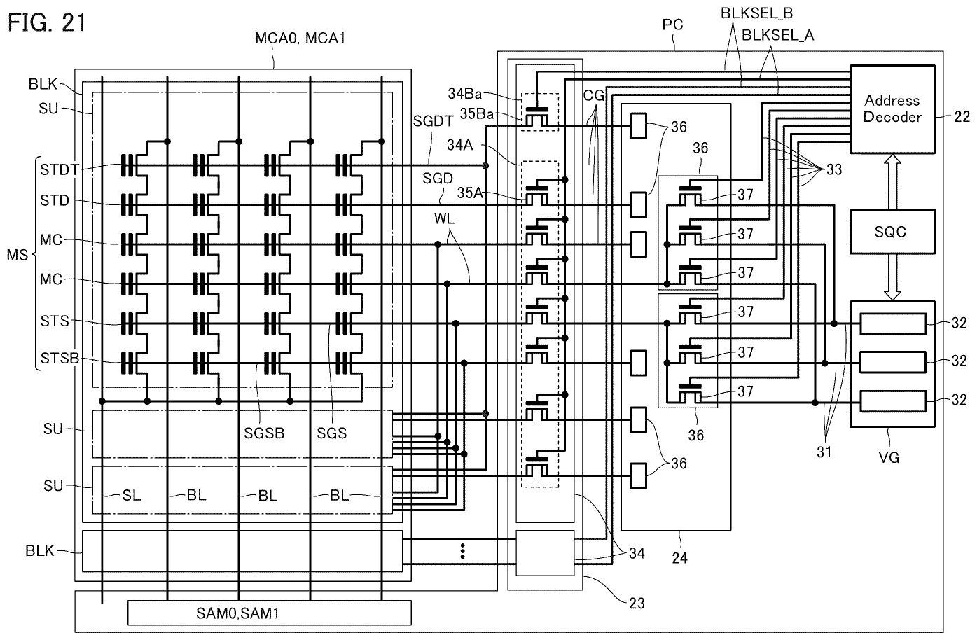

Next, with reference to FIG. 21, the modification of the semiconductor memory device according to the first embodiment is described. FIG. 21 is a schematic circuit diagram illustrating a configuration of a part of the semiconductor memory device according to the modification.

The semiconductor memory device according to this modification is configured basically similarly to the semiconductor memory device according to the first embodiment. However, the semiconductor memory device according to this modification includes a drain-side select transistor STDT connected between the bit line BL and the drain-side select transistor STD in series. The drain-side select transistor STDT is, for example, a transistor disposed to generate GIDL as described above. To a gate electrode of the drain-side select transistor STDT, the drain-side select gate line SGDT is connected. The drain-side select gate line SGDT is connected in common to all the memory strings MS in the memory block BLK.

The semiconductor memory device according to this modification includes a block select circuit 34Ba and a block select transistor 35Ba instead of the block select circuit 34B and the block select transistor 35B.

The block select circuit 34Ba includes a block select transistor 35Ba corresponding to the drain-side select gate line SGDT. The block select transistor 35Ba is, for example, a field-effect type high breakdown voltage transistor. The block select transistor 35Ba has a drain electrode electrically connected to the drain-side select gate line SGDT. The block select transistor 35Ba has a source electrode electrically connected to the voltage supply line 31 via the wiring CG and the voltage select circuit 24. The block select transistor 35Ba has a gate electrode connected to the corresponding block select line BLKSEL_B.

In the erase operation, the address decoder 22 performs an operation similar to the first embodiment on the block select line BLKSEL_B. That is, to the drain-side select gate line SGDT of the unselected memory block BLK_{ntb}, the above-described voltage V_{ERA} required for the erase operation is applied via the wiring CG and the block select transistor 35Ba.

### Second Embodiment

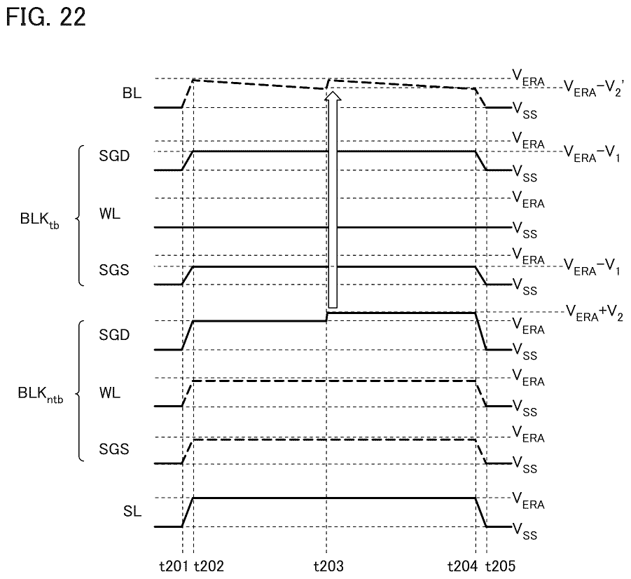

Next, with reference to FIG. 22, a configuration of a semiconductor memory device according to the second embodiment is described. The semiconductor memory device according to the embodiment is basically configured similarly to the semiconductor memory device according to the first embodiment. However, the semiconductor memory device according to the second embodiment is different from the first embodiment in a method of an erase operation.

[Erase Operation]

The erase operation of the semiconductor memory device according to the embodiment is described. FIG. 22 is a schematic waveform diagram for describing the erase operation of the semiconductor memory device according to the second embodiment. In the following description, the configuration and the operation similar to those of the first embodiment are omitted in some cases.

At timing t201 of the erase operation, the bit line BL is set to a floating state. In the select memory block BLK_{tb}, the voltage V_{ERA}−V₁ is applied to the respective select gate lines (SGD, SGS) and the ground voltage V_{SS} is applied to the word line WL. In the unselected memory block BLK_{cntb}, the voltage V_{ERA} is applied to the drain-side select gate line SGD and the word line WL and the source-side select gate line SGS are set to a floating state. The voltage V_{ERA} is applied to the source line SL (semiconductor layer 112).

At timing t202, similarly to the first embodiment, by capacitive coupling with the drain-side select gate line SGD of the unselected memory block BLK_{ntb}, the voltage of the bit line BL increases to a value same as the voltage V_{ERA} or close to the voltage V_{ERA} from the ground voltage V_{SS}.

From timing t202 to timing t204, by the above-described holes generated by GIDL, data written to the memory cell MC is erased. Note that by the supply of electrons generated by GIDL to the bit line BL, the voltage of the bit line BL decreases to a voltage V_{ERA}−V₂′, which is found by subtracting a voltage V₂′ from the voltage V_{ERA}, from timing t202 to timing t203. Although the voltage V_{ERA}−V₂′ is a voltage lower than the voltage V_{ERA}, it has a magnitude to the extent that the erase operation by GIDL can be performed.

At timing t203, the drain-side select gate line SGD of the unselected memory block BLK_{ntb} is increased from the voltage V_{ERA} to a voltage V_{ERA}+V₂ larger than the voltage V_{ERA}. The voltage V₂ has a magnitude to the extent that the voltage of the bit line BL can be the same as or increase again to a value close to the voltage V_{ERA} by the capacitive coupling described above. The voltage V₂ may have about the same magnitude as a magnitude of the voltage V₂′ or larger than the voltage V_{2′}.

From timing t203 to timing t204 as well, similarly to from timing t202 to timing t203, the voltage of the bit line BL decreases from the voltage V_{ERA} to the voltage V_{ERA}−V₂′ by the electrons generated by GIDL.

At timing t204, the ground voltage V ss is applied to the select gate lines (SGD, SGS) and the word lines WL of the select memory block BLK_{tb} and the unselected memory block BLK_{ntb}.

[Effects]

When the voltage of the bit line BL decreases from the voltage V_{ERA} to a predetermined voltage or more while the erase operation is performed on the memory cell MC, efficiency of the erase operation on the memory cell MC decreases and when the voltage further decreases, erase cannot be performed in some cases.

As in this embodiment, when the voltage of the drain-side select gate line SGD of the unselected memory block BLK_{ntb}, is increased to the voltage V_{ERA}+V₂ in the middle of the erase operation, a significant decrease in the voltage of the bit line BL from the voltage V_{ERA} can be reduced. Accordingly, the stable erase operation can be performed without the increase in the circuit area as in the comparative example described above. Accordingly, high integration of the operation of the semiconductor memory device can be achieved.

### Third Embodiment

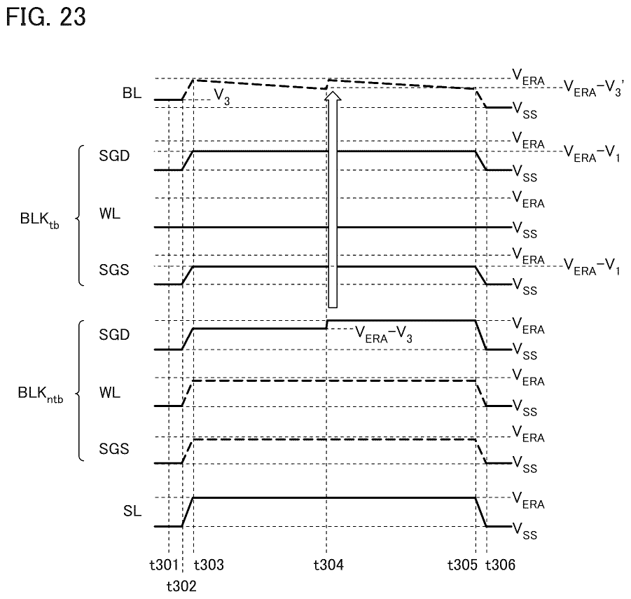

Next, with reference to FIG. 23, a configuration of a semiconductor memory device according to the third embodiment is described. The semiconductor memory device according to the embodiment is configured basically similarly to the semiconductor memory device according to the first embodiment. However, the semiconductor memory device according to the third embodiment is different from the first embodiment in a method of an erase operation.

[Erase Operation]

The erase operation of the semiconductor memory device according to the embodiment is described. FIG. 23 is a schematic waveform diagram for describing the erase operation of the semiconductor memory device according to the third embodiment. In the following description, the configuration and the operation similar to those of the first embodiment are omitted in some cases.

At timing t301 of the erase operation, a voltage V₃ is applied to the bit line BL to charge the bit line BL. The bit line BL may be charged, for example, by the voltage supply line to which the voltage V_{DD} connected to the sense amplifier unit SAU (FIG. 11) is applied. In this case, for example, the voltage V₃ has about the same magnitude as a magnitude of the voltage V_{DD} connected to the sense amplifier unit SAU.

At timing t302 of the erase operation, the bit line BL is set to a floating state. In the select memory block BLK_{tb}, the voltage V_{ERA}−V₁ is applied to the respective select gate lines (SGD, SGS) and the ground voltage V_{SS} is applied to the word line WL. In the unselected memory block BLK_{ntb}, a voltage V_{ERA}−V₃ is applied to the drain-side select gate line SGD and the word line WL and the source-side select gate line SGS are set to a floating state. The voltage V_{ERA} is applied to the source line SL (semiconductor layer 112).

At timing t303, similarly to the first embodiment, the voltage of the bit line BL becomes the same as the voltage V_{ERA} or increases to a value close to the voltage V_{ERA} from the voltage V₃ by capacitive coupling with the drain-side select gate line SGD of the unselected memory block BLK_{ntb}.

From timing t303 to timing t305, by GIDL described above, data written to the memory cell MC is erased. Note that by the supply of the electrons generated by GIDL to the bit line BL, the voltage of the bit line BL decreases to a voltage V_{ERA}−V₃′, which is found by subtracting the voltage V₃′ from the voltage V_{ERA}, from timing t303 to timing t304. Although the voltage V_{ERA}−V₃′ is a voltage lower than the voltage V_{ERA}, it has a magnitude to the extent that the erase operation by GIDL can be performed.

At timing t304, the voltage of the drain-side select gate line SGD of the unselected memory block BLK_{ntb} increases to the voltage V_{ERA} from V_{ERA}−V₃. Thus, the voltage of the bit line BL becomes the same as the voltage V_{ERA} or increases again to a value close to the voltage V_{ERA} by the capacitive coupling described above. Note that the voltage V₃ may have about the same magnitude as a magnitude of the voltage V₃′ or larger than the voltage V₃′.

From timing t304 to timing t305 as well, similarly to from timing t303 to timing t304, the voltage of the bit line BL decreases from the voltage V_{ERA} to the voltage V_{ERA}−V₃′ by the electrons generated by GIDL.

At timing t305, the ground voltage V_{SS} is applied to the select gate lines (SGD, SGS) and the word lines WL of the select memory block BLK_{tb} and the unselected memory block BLK_{ntb}.

[Effects]

As in this embodiment, by performing initial charge on the bit line BL up to the voltage V₃, at an early stage of the erase operation, the voltage applied to the drain-side select gate line SGD of the unselected memory block BLK_{ntb} is lower than the voltage V_{ERA}. Accordingly, the erase operation can be performed at further low power consumption.

### OTHERS

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a first wiring;
a first memory transistor connected to the first wiring;
a first transistor connected between the first wiring and the first memory transistor;
a second memory transistor connected to the first wiring in parallel with the first memory transistor;
a second transistor connected between the first wiring and the second memory transistor;
a second wiring connected to a gate electrode of the first memory transistor;
a third wiring connected to a gate electrode of the second memory transistor;
a first gate wiring connected to a gate electrode of the first transistor;
a second gate wiring connected to a gate electrode of the second transistor; and
a control circuit configured to be able to execute an erase operation that selects the first memory transistor or the second memory transistor and erases data, wherein
the control circuit is configured to be able to control a voltage of the first gate wiring to become larger than a voltage of the second wiring and control a voltage of the second gate wiring to become larger than the voltage of the first gate wiring in the erase operation performed with the first memory transistor selected.

2. The semiconductor memory device according to claim 1, wherein
the control circuit is configured to be able to apply a first voltage to the second gate wiring from a first timing to a second timing after the first timing and apply a second voltage larger than the first voltage to the second gate wiring from the second timing to a third timing after the second timing in the erase operation performed with the first memory transistor selected.

3. The semiconductor memory device according to claim 2, wherein
the control circuit is configured to be able to apply a voltage smaller than the second voltage to the first gate wiring from the first timing to the third timing.

4. The semiconductor memory device according to claim 2, wherein
the control circuit is configured to be able to apply a third voltage to the first gate wiring and apply a fourth voltage larger than the third voltage to the first wiring from a fourth timing before the first timing to the first timing.

5. The semiconductor memory device according to claim 1, wherein
the control circuit is configured to be able to set the first wiring in a floating state in the erase operation.

6. The semiconductor memory device according to claim 1, comprising:
a substrate;
a plurality of first conductive layers arranged in a first direction intersecting with a surface of the substrate;
a first semiconductor column extending in the first direction and opposed to the plurality of first conductive layers;
a gate insulating layer disposed between the plurality of first conductive layers and the first semiconductor column;
a plurality of second conductive layers spaced from the plurality of first conductive layers in a second direction intersecting with the first direction and arranged in the first direction;
a second semiconductor column extending in the first direction and opposed to the plurality of second conductive layers; and
a gate insulating layer disposed between the plurality of second conductive layers and the second semiconductor column, wherein
the first memory transistor includes a part of a third conductive layer as one of the plurality of first conductive layers, a first region of the first semiconductor column opposed to the third conductive layer, and an electric charge accumulating film disposed between the third conductive layer and the first semiconductor column, and
the first transistor includes a part of a fourth conductive layer far from the substrate than the third conductive layer and a second region of the first semiconductor column opposed to the fourth conductive layer.

7. A semiconductor memory device comprising:
a first wiring;
a first voltage supply line;
a first memory transistor connected between the first wiring and the first voltage supply line;
a first transistor connected between the first wiring and the first memory transistor;
a second memory transistor connected between the first wiring and the first voltage supply line in parallel with the first memory transistor;
a second transistor connected between the first wiring and the second memory transistor;
a first gate wiring connected to a gate electrode of the first transistor;
a second gate wiring connected to a gate electrode of the second transistor; and
a control circuit configured to be able to execute an erase operation that selects the first memory transistor or the second memory transistor and erases data, wherein
the control circuit is configured to be able to control a voltage of the second gate wiring to become the same as or larger than a voltage of the first voltage supply line in the erase operation performed with the first memory transistor selected.

8. The semiconductor memory device according to claim 7, wherein
the control circuit is configured to be able to control the voltage of the second gate wiring to become larger than a voltage of the first gate wiring in the erase operation performed with the first memory transistor selected.

9. The semiconductor memory device according to claim 7, wherein
the control circuit is configured to be able to apply a first voltage to the second gate wiring from a first timing to a second timing after the first timing and apply a second voltage larger than the first voltage to the second gate wiring from the second timing to a third timing after the second timing in the erase operation performed with the first memory transistor selected.

10. The semiconductor memory device according to claim 9, wherein
the control circuit is configured to be able to apply a voltage smaller than the second voltage to the first gate wiring from the first timing to the third timing.

11. The semiconductor memory device according to claim 9, wherein
the control circuit is configured to be able to apply a third voltage to the first gate wiring and apply a fourth voltage larger than the third voltage to the first wiring from a fourth timing before the first timing to the first timing.

12. The semiconductor memory device according to claim 7, wherein
the control circuit is configured to be able to set the first wiring in a floating state in the erase operation.

13. The semiconductor memory device according to claim 7, comprising:
a substrate;
a plurality of first conductive layers arranged in a first direction intersecting with a surface of the substrate;
a first semiconductor column extending in the first direction and opposed to the plurality of first conductive layers;
a gate insulating layer disposed between the plurality of first conductive layers and the first semiconductor column;
a plurality of second conductive layers spaced from the plurality of first conductive layers in a second direction intersecting with the first direction and arranged in the first direction;
a second semiconductor column extending in the first direction and opposed to the plurality of second conductive layers; and
a gate insulating layer disposed between the plurality of second conductive layers and the second semiconductor column, wherein
the first memory transistor includes a part of a third conductive layer as one of the plurality of first conductive layers, a first region of the first semiconductor column opposed to the third conductive layer, and an electric charge accumulating film disposed between the third conductive layer and the first semiconductor column, and
the first transistor includes a part of a fourth conductive layer far from the substrate than the third conductive layer and a second region of the first semiconductor column opposed to the fourth conductive layer.

14. The semiconductor memory device according to claim 7, comprising:
a third transistor connected between the first voltage supply line and the first memory transistor; and
a third gate wiring connected to a gate electrode of the third transistor, wherein
the control circuit is configured to be able to control a voltage of the third gate wiring to become smaller than a voltage of the first voltage supply line in the erase operation.

15. The semiconductor memory device according to claim 14, comprising:
a fourth transistor connected between the first voltage supply line and the second memory transistor; and
a fourth gate wiring connected to a gate electrode of the fourth transistor, wherein
the control circuit is configured to be able to set the fourth gate wiring in a floating state in the erase operation.

16. The semiconductor memory device according to claim 1, wherein
the control circuit includes:
a voltage generation circuit configured to be able to generate a plurality of voltage levels;
a voltage select circuit connected to the voltage generation circuit and selecting the plurality of voltage levels;
a first select transistor and a second select transistor connected in parallel between the voltage select circuit and the first transistor; and
a third select transistor and a fourth select transistor connected in parallel between the voltage generation circuit and the second transistor.

17. The semiconductor memory device according to claim 16, wherein
in a read operation performed with the first memory transistor selected, the control circuit is configured to be able to set:
the first select transistor to an ON state;
the second select transistor to an OFF state;
the third select transistor to an OFF state; and
the fourth select transistor to an OFF state;
in the read operation performed with the second memory transistor selected, the control circuit is configured to be able to set:
the first select transistor to an OFF state;
the second select transistor to the OFF state;
the third select transistor to an ON state; and
the fourth select transistor to the OFF state, and
in the erase operation performed with the first memory transistor selected, the control circuit is configured to be able to set:
the first select transistor to the ON state;
the second select transistor to the OFF state;
the third select transistor to the OFF state; and
the fourth select transistor to an ON state.
